(19) United States
(12) Patent Application Publication
(10) Pub. No.: US 2020/0218391 A1
(43) Pub. Date: Jul. 9, 2020

(54) DISPLAY DEVICE

(71) Applicant: Japan Display Inc., Tokyo (JP)

(72) Inventor: Akinori KAMIYA, Tokyo (JP)

(21) Appl. No.: 16/824,894

(22) Filed: Mar. 20, 2020

Related U.S. Application Data
(63) Continuation of application No. PCT/JP2018/028943, filed on Aug. 1, 2018.

(30) Foreign Application Priority Data
Sep. 25, 2017 (JP) 2017-183964

(51) Int. Cl. G06F 3/041; G06F 3/042; H01L 27/32; H01L 51/52; H01L 51/56; G06F 3/044

(52) U.S. Cl. CPC G06F 3/0412; G06F 3/042; H01L 27/323; H01L 27/3246; H01L 27/3276; G06F 2203/04107; H01L 51/5281; H01L 51/56; G06F 3/0445; G06F 2203/04103; H01L 51/5253

(57) ABSTRACT

A display device includes a display region including a plurality of pixels each including a light emitting element; a sealing film provided on the display region; an insulating layer provided on the sealing film; a first sensor electrode including a first conductive layer and a second conductive layer provided on the insulating layer and a connection electrode covered with the insulating layer, at least a part of the connection electrode being embedded in the sealing film; and a second sensor electrode provided on the insulating layer. The first conductive layer is connected to the second conductive layer via the connection electrode. The connection electrode includes a region crossing at least a part of the second sensor electrode.

### CROSS REFERENCE TO RELATED APPLICATIONS

This application is based upon and claims the benefit of priority from the prior Japanese Patent Application No. 2017-183964 filed on Sep. 25, 2017, and PCT Application No. PCT/JP2018/28943 filed on Aug. 1, 2018, the entire contents of which are incorporated herein by reference.

### FIELD

One embodiment of the present invention relates to a display device including a touch sensor, for example, an EL (Electroluminescence) display device including a touch sensor.

### BACKGROUND

A touch sensor is known as an interface usable by a user to input information on a display device. A touch sensor is installed so as to overlap a screen of a display device, so that the user may operate an input button, an icon or the like displayed on the screen and thus may easily input information on the display device. For example, Patent Literature 1 (Japanese Laid-Open Patent Publication No. 2015-72662) discloses an electronic device including an organic EL display device and a touch sensor mounted thereon. In this electronic device, a sealing film is formed on an organic EL element (hereinafter, referred to as a “light emitting element”), and a sensor electrode for the touch sensor is formed thereon.

### SUMMARY

A display device according to an embodiment of the present invention includes a display region including a plurality of pixels each including a light emitting element; a sealing film provided on the display region; an insulating layer provided on the sealing film; a first sensor electrode including a first conductive layer and a second conductive layer provided on the insulating layer and a connection electrode covered with the insulating layer, at least a part of the connection electrode being embedded in the sealing film; and a second sensor electrode provided on the insulating layer. The first conductive layer is connected to the second conductive layer via the connection electrode. The connection electrode includes a region crossing at least a part of the second sensor electrode.

A display device according to an embodiment of the present invention includes a display region including a plurality of pixels each including a light emitting element; a sealing film provided on the display region; an insulating layer provided on the sealing film; a first sensor electrode including a connection electrode provided on the insulating layer and a first conductive layer and a second conductive layer covered with the insulating layer, at least a part of the first conductive layer e being embedded in the sealing film, at least a part of the second conductive layer e being embedded in the sealing film; and a second sensor electrode, at least a part of the second electrode being embedded in the sealing film. The first conductive layer is connected to the second conductive layer via the connection electrode. The connection electrode includes a region crossing at least a part of the second sensor electrode.

A display device according to an embodiment of the present invention includes a display region including a plurality of pixels each including a light emitting element; an organic insulating layer provided above the plurality of pixels and covering the plurality of pixels; a first inorganic insulating layer in contact with the organic insulating layer, the organic insulating layer being located between the first inorganic insulating layer and the plurality of pixels; a second inorganic insulating layer in contact with the first inorganic insulating layer, the first inorganic insulating layer being located between the second inorganic insulating layer and the organic insulating layer; a first sensor electrode including a first conductive layer and a second conductive layer in contact with the second inorganic insulating layer, the first conductive layer and the second conductive layer being separate from each other and located at a same layer; a connection electrode connecting the first conductive layer to the second conductive layer, the second inorganic insulating layer being located between the first sensor electrode and the connection electrode; and a second sensor electrode located at a same layer as that of the first sensor electrode. The first inorganic insulating layer includes a first recessed portion. One of the first sensor electrode and the connection electrode is located between the first inorganic insulating layer and the second inorganic insulating layer. At least a part of the one of the first sensor electrode and the connection electrode is located in the first recessed portion. The connection electrode includes a region crossing at least a part of the second sensor electrode.

### BRIEF DESCRIPTION OF DRAWINGS

FIG. 1 is a schematic view showing a display region of a display device according to an embodiment of the present invention;

FIG. 2 is a schematic view showing a touch sensor of the display device according to an embodiment of the present invention;

FIG. 3 is a schematic view showing the touch sensor of the display device according to an embodiment of the present invention;

FIG. 4 is a schematic view showing the touch sensor of the display device according to an embodiment of the present invention;

FIG. 5 is a cross-sectional view showing the display device according to an embodiment of the present invention;

FIG. 6A is a cross-sectional view showing a sensor electrode of the display device according to an embodiment of the present invention;

FIG. 6B is a cross-sectional view showing a sensor electrode of the display device according to an embodiment of the present invention;

FIG. 7 shows a layout of a sensor electrode of the display device according to an embodiment of the present invention;

FIG. 8 is a cross-sectional view showing the touch sensor of the display device according to an embodiment of the present invention;

FIG. 9A shows a method for producing a sealing film and the touch sensor of the display device according to an embodiment of the present invention;

FIG. 9B shows the method for producing the sealing film and the touch sensor of the display device according to an embodiment of the present invention;

FIG. 9C shows the method for producing the sealing film and the touch sensor of the display device according to an embodiment of the present invention;

FIG. 9D shows the method for producing the sealing film and the touch sensor of the display device according to an embodiment of the present invention;

FIG. 9E shows the method for producing the sealing film and the touch sensor of the display device according to an embodiment of the present invention;

FIG. 9F shows the method for producing the sealing film and the touch sensor of the display device according to an embodiment of the present invention;

FIG. 10 is a schematic view showing a touch sensor of the display device according to an embodiment of the present invention;

FIG. 11A is a cross-sectional view showing a sensor electrode of the display device according to an embodiment of the present invention;

FIG. 11B is a cross-sectional view showing a sensor electrode of the display device according to an embodiment of the present invention;

FIG. 12 is a schematic view showing a touch sensor of the display device according to an embodiment of the present invention;

FIG. 13 is a cross-sectional view showing the touch sensor of the display device according to an embodiment of the present invention;

FIG. 14A shows a method for producing a sealing film and the touch sensor of the display device according to an embodiment of the present invention;

FIG. 14B shows the method for producing the sealing film and the touch sensor of the display device according to an embodiment of the present invention;

FIG. 14C shows the method for producing the sealing film and the touch sensor of the display device according to an embodiment of the present invention;

FIG. 14D shows the method for producing the sealing film and the touch sensor of the display device according to an embodiment of the present invention;

FIG. 14E shows the method for producing the sealing film and the touch sensor of the display device according to an embodiment of the present invention;

FIG. 14F shows the method for producing the sealing film and the touch sensor of the display device according to an embodiment of the present invention; and

FIG. 15 shows a comparative example of a structure of a sealing film and a touch sensor.

### DESCRIPTION OF EMBODIMENTS

One of objects of the present invention is to prevent disconnection of a sensor electrode provided on a sealing film in a display device including a touch sensor.

Hereinafter, embodiments of the present invention will be described with reference to the drawings and the like. The present invention may be carried out in various forms without departing from the gist thereof, and is not to be construed as being limited to any of the following embodiments.

In the drawings, components may be shown schematically regarding the width, thickness, shape and the like, instead of being shown in accordance with the actual forms, for the sake of clearer illustration. The schematic drawings are merely examples and do not limit the interpretations of the present invention in any way. In the specification and the drawings, components that have substantially the same functions as those described before with reference to a previous drawing(s) bear the identical reference signs thereto, and repetitive descriptions thereof may be omitted.

In the present invention, in the case where one film is processed to form a plurality of films, the plurality of films may have different functions or roles. However, the plurality of films are derived from the film formed in the same step as the same layer, and have the same layer structure and are formed of the same material. Therefore, the plurality of films are defined as being present in the same layer.

In the specification and the claims, an expression that a component is “on” another component encompasses a case where such a component is in contact with the another component, and also a case where such a component is above or below the another component, namely, a case where still another component is provided between such a component and the another component, unless otherwise specified.

### Embodiment 1

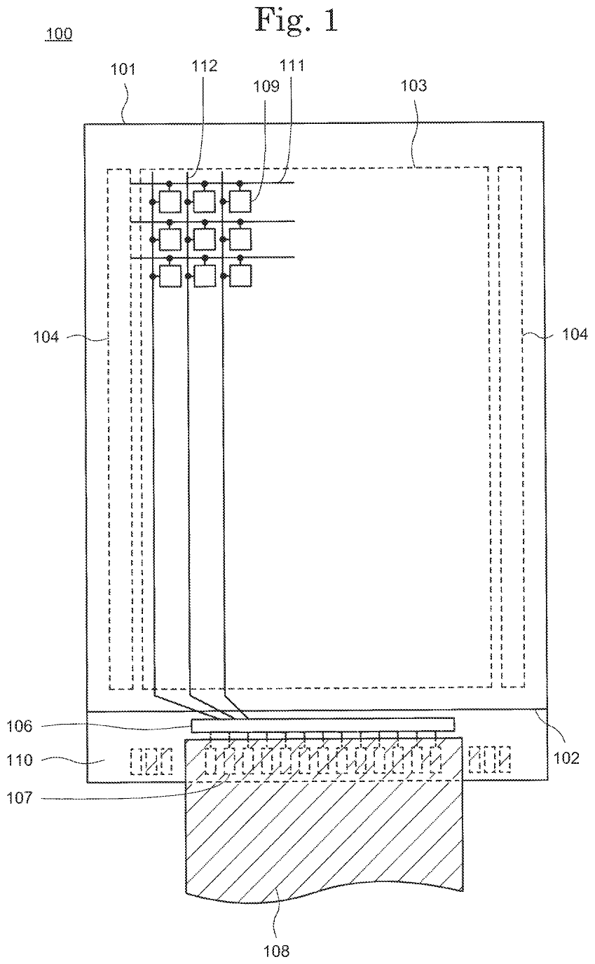

With reference to FIG. 1 to FIG. 9F, a display device 100 according to this embodiment will be described.

### [Display Region]

FIG. 1 is a schematic view showing a display region 103 of the display device 100 according to this embodiment, and is a schematic view of the display region 103 as seen in a plan view. In this specification and the like, a view of the display device 100 as seen in a direction perpendicular to a screen (display region 103) will be referred to as being “seen in a plan view”.

As shown in FIG. 1, the display device 100 includes the display region 103 formed on an insulating surface, a scanning line driving circuit 104, and a driver IC 106. Herein, the insulating surface is a surface of a substrate 101. Usable as the substrate 101 may be a flexible resin substrate (flexible resin substrate formed of polyimide, polyethyleneterephthalate, polyethylenenaphthalate, triacetylcellulose, cyclic olefin-copolymer, cycloolefin polymer or the like). Use of a flexible resin substrate allows the display device to be bent. It is preferred that the substrate 101 is formed of a light-transmissive material. A substrate substantially the same as the substrate 101 is usable for a substrate 102. In the case where the substrate does not need to be bent, the substrate may be a glass substrate, a metal substrate, a ceramic substrate, a semiconductor substrate or the like.

A plurality of pixels 109 each including a light emitting element are provided in the display region 103. The display region 103 is surrounded by a peripheral region 110. The driver IC 106 acts as a controller that supplies a signal to the scanning line driving circuit 104. A signal line driving circuit is incorporated into the driver IC 106. FIG. 1 shows an example in which the driver IC 106 is provided on the substrate 101. Alternatively, the driver IC 106 may be provided on a flexible printed circuit board 108 as an external component. The flexible printed circuit board 108 is connected with a plurality of terminals 107 provided in the peripheral region 110.

A plurality of scanning lines 111 provided to extend in a first direction and a plurality of signal lines 112 provided to extend in a second direction crossing the first direction are provided in the display region 103. The pixels 109 connected with the scanning lines 111 and the signal lines 112 are located in a matrix. The pixels 109 each include a light emitting element and a transistor. The light emitting element includes at least a pixel electrode (anode), an organic layer (light emitting portion) including a light emitting layer stacked on the pixel electrode and a negative electrode (cathode). The plurality of pixels 109 are each supplied with a data signal in accordance with image data from the signal line driving circuit via the signal line 112. The transistor electrically connected with the pixel electrode provided in each of the plurality of pixels 109 is driven in accordance with the data signal, and thus an image may be displayed on the screen in accordance with the image data. As the transistor, a thin film transistor (TFT) is typically usable. The transistor is not limited to a thin film transistor, and may be any element having an electric current control function.

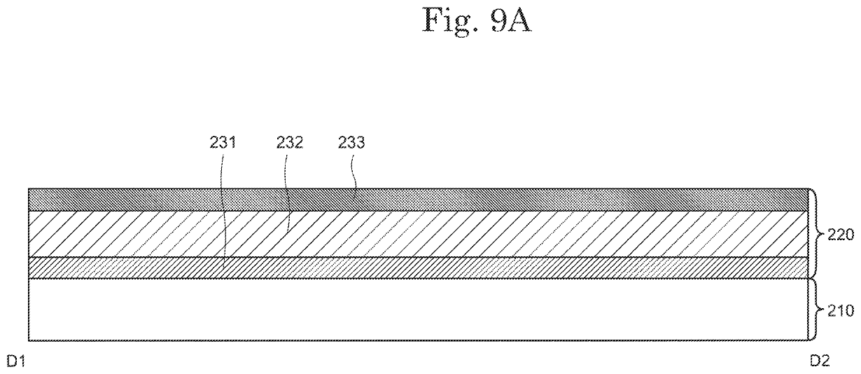

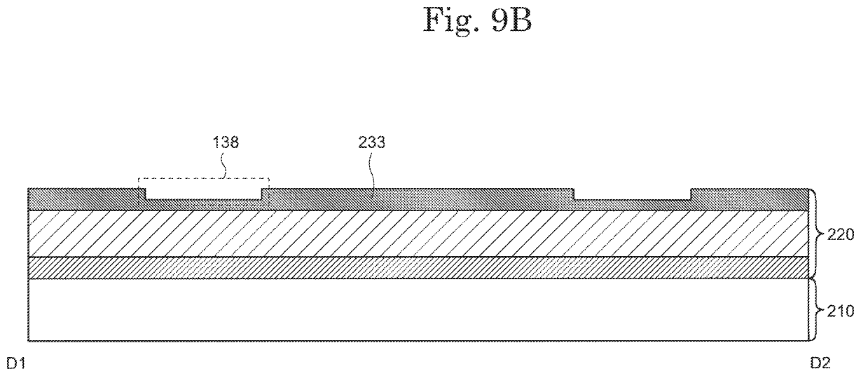

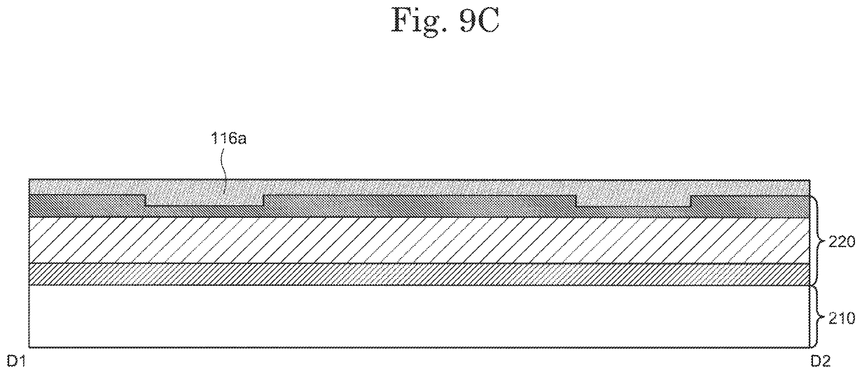

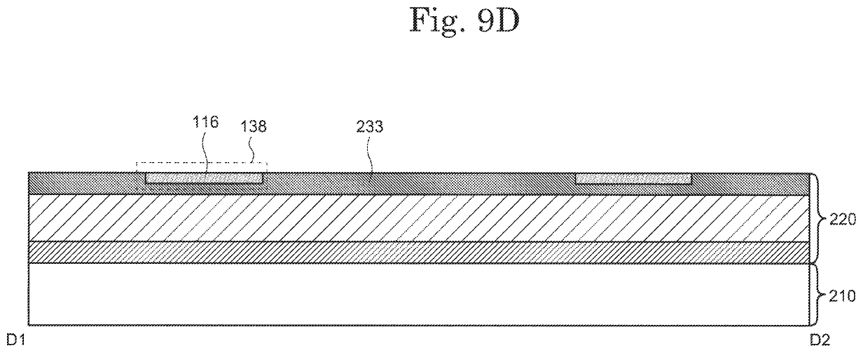

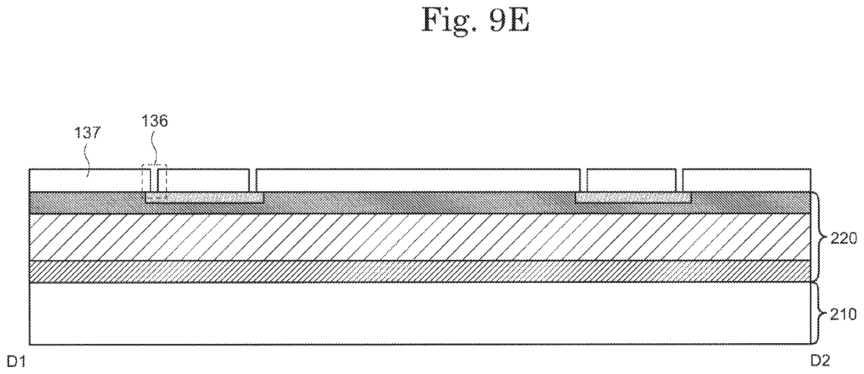

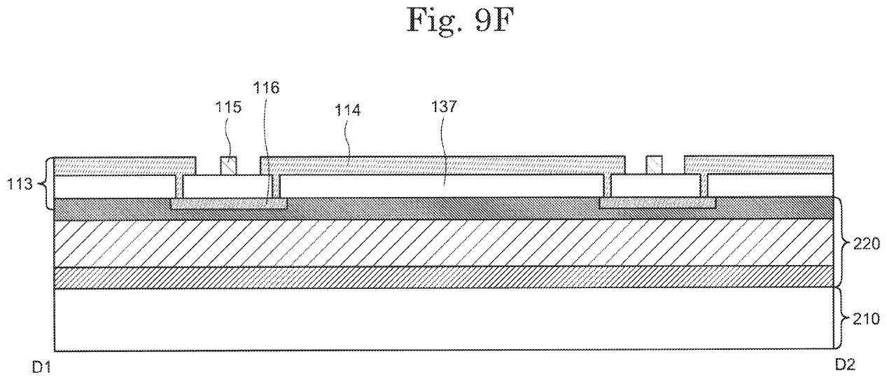

Although not shown in FIG. 1, a sealing film is provided on the display region 103 to protect the light emitting elements against moisture or oxygen. The sealing film has a structure in which, for example, an inorganic insulating layer and an organic insulating layer are alternately stacked. The structure of a sealing film 220 will be described below in detail (see FIG. 9A).

### [Touch Sensor]

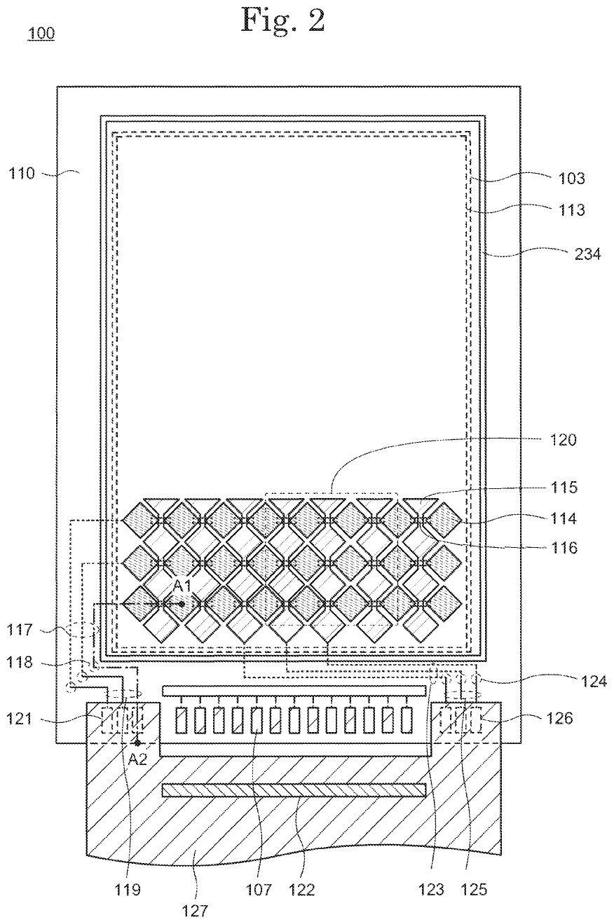

FIG. 2 is a schematic view showing a touch sensor 113 of the display device 100 according to this embodiment, and is a schematic view of the display region 103 as seen in a plan view.

The touch sensor 113 is provided so as to overlap the display region 103. The touch sensor 113 includes a plurality of sensor electrodes 114 extending in stripes in a row direction and a plurality of sensor electrodes 115 extending in stripes in a column direction. One of the sensor electrodes 114 and the sensor electrodes 115 are referred to also as “transmission electrodes (Tx)”, and the other of the sensor electrodes 114 and the sensor electrodes 115 are referred to also as “receiving electrodes (Rx)”. Each of the sensor electrodes 114 and each of the sensor electrodes 115 are separate from each other, and a capacitance is formed between each of the sensor electrodes 114 and each of the sensor electrodes 115. For example, a human finger or the like contacts the display region 103 (hereinafter, such a contact will be referred to as a “touch”) via the sensor electrode 114 and the sensor electrode 115 to change the capacitance, and such change is read, so that the position of the touch is determined. As can be seen, the sensor electrodes 114 and the sensor electrodes 115 form the touch sensor 113 of a so-called projected capacitance type.

Regarding the following description, the sensor electrodes 114 and the sensor electrodes 115 are shown with different types of hatching in order to be distinguished from each other. However, the sensor electrodes 114 and the sensor electrodes 115 are formed of the same conductive layer.

The sensor electrodes 114 are electrically connected with wires 117 located in the peripheral region 110 around the display region 103. The wires 117 extend in the peripheral region 110 and are electrically connected with wires 119 in contact holes 118. The wires 119 are exposed in the vicinity of an end of the peripheral region 110 to form terminals 121. The terminals 121 are connected with a flexible printed circuit board 127, and a touch sensor signal is supplied to the sensor electrodes 114 from a driver IC 122 via the terminals 121. The wires 117 may be provided in a region overlapping the scanning line driving circuit 104.

Similarly, the sensor electrodes 115 are electrically connected with wires 123 located in the peripheral region 110 around the display region 103. The wires 123 extend in the peripheral region 110 and are electrically connected with wires 125 via contact holes 124. The wires 125 are exposed in the vicinity of an end of the peripheral region 110 to form terminals 126. The terminals 126 are connected with the flexible printed circuit board 127, and a touch sensor signal is supplied to the sensor electrodes 115 from the driver IC 122 via the terminals 126. The terminals 107, the terminals 121 and the terminals 126 are provided along one side of the substrate 101. In the peripheral region 110, a bank 234 is provided so as to surround the display region 103.

### [Sensor Electrodes]

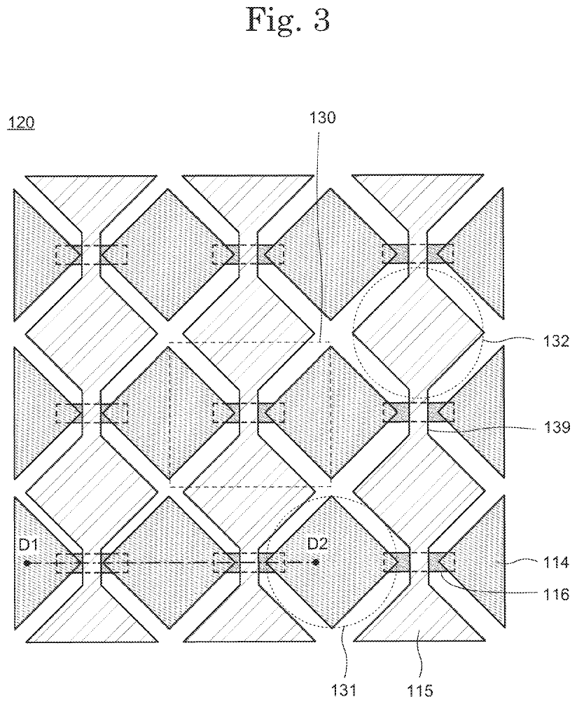

The touch sensor 113 includes the plurality of sensor electrodes 114 extending in the row direction and the plurality of sensor electrodes 115 extending in the column direction. FIG. 3 is an enlarged view of a region 120 shown in FIG. 2. The sensor electrodes 114 each include a plurality of conductive layers 131 each having a generally rectangular shape and connection electrodes 116. The sensor electrodes 115 also each include a plurality of conductive layers 132 each having a generally rectangular shape and connection regions 139. The sensor electrodes 114 and the sensor electrodes 115 are separate from each other and electrically independent from each other.

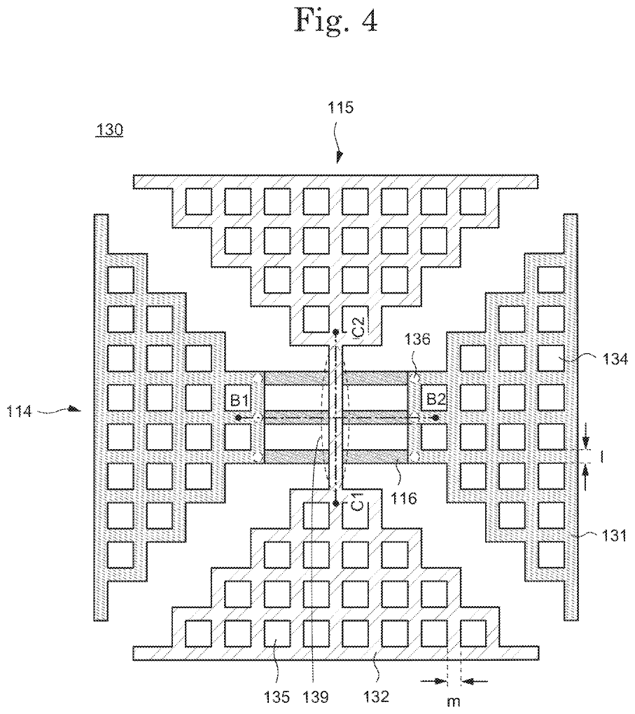

FIG. 4 is an enlarged view of a region 130 shown in FIG. 3. The conductive layers 131, of the sensor electrode 114, adjacent to each other in a left-right direction are connected with each other via the connection electrode 116. The conductive layers 132, of the sensor electrode 115, adjacent to each other in an up-down direction are connected with each other via the connection region 139. The plurality of conductive layers 131 included in the connection electrode 114 each include a plurality of openings 134, and the plurality of conductive layers 132 included in the connection electrode 115 each include a plurality of openings 135. Respectively in each conductive layer 131 and each conductive layer 132, the plurality of openings 134 and the plurality of openings 135 are arrayed in a matrix. As a result, the conductive layer 131 and the conductive layer 132 each have a mesh form (or a lattice form). Width I of a wire forming the conductive layer 131 is 1 μm or greater and 10 μm or less, or 2 μm or greater and 8 μm or less, and typically 5 μm. Similarly, width m of a wire forming the conductive layer 132 is 1 μm or greater and 10 μm or less, or 2 μm or greater and 8 μm or less, and typically 5 μm.

As shown in FIG. 4, the connection electrode 116 connecting the conductive layers 131 adjacent to each other in the left-right direction is provided to extend in the first direction, and the connection region 139 connecting the conductive layers 132 adjacent to each other in the up-down direction is provided to extend in the second direction crossing the first direction. In other words, the connection electrode 116 includes a region crossing a part of the sensor electrode 115. In FIG. 4, the connection electrode 116 is shown as having a width that is the same as the width I of the conductive layer 131, but the width of the connection electrode 116 may be greater than the width I of the conductive layer 131. It is preferred that the connection electrode 116 does not overlap a light emitting region of the pixel.

### [Cross-Sectional Structure of the Display Device]

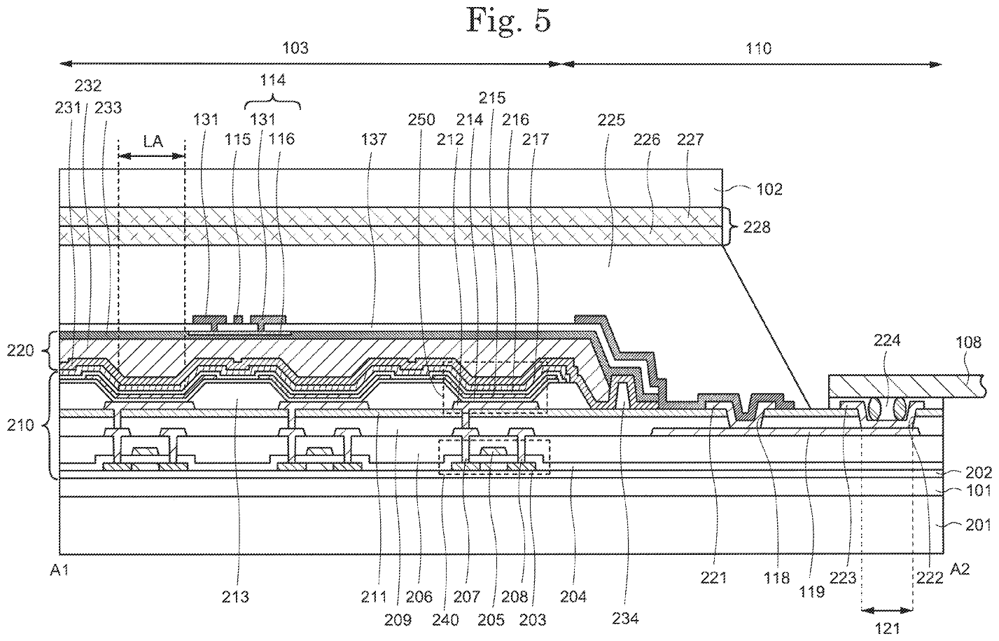

Now, with reference to FIG. 5, a cross-sectional structure of a range, of the display device 100, including a region from the display region 103 to the terminals 107 will be described. FIG. 5 shows a structure of the cross-section taken along line A1-A2 in FIG. 1.

As shown in FIG. 5, the display device 100 includes the substrate 101, the substrate 102, and a support substrate 201. Usable as each of the substrate 101, the substrate 102 and the support substrate 201 may be a glass substrate, a quartz substrate or a flexible substrate (flexible resin substrate formed of polyimide, polyethyleneterephthalate, polyethylenenaphthalate, triacetylcellulose, cyclic olefin-copolymer, cycloolefin polymer or the like).

On the substrate 101, an underlying film 202 is provided. The underlying film 202 is an insulating layer formed of an inorganic insulating material such as silicon oxide, silicon nitride, aluminum oxide or the like. The underlying film 202 is not limited to being a single layer, and may have a stack structure including a combination of, for example, a silicon oxide layer and a silicon nitride layer. The structure may be appropriately determined in consideration of the adhesiveness with the substrate 101 or the gas barrier property to transistors 240.

On the underlying layer 202, the transistors 240 are provided. The transistors 240 may each be of a top gate type or a bottom gate type. In this embodiment, the transistor 240 includes a semiconductor layer 203 provided on the underlying film 202, a gate insulating film 204 covering the semiconductor layer 203, and a gate electrode 205 provided on the gate insulating film 204.

Each of the layers included in the transistor 240 will be described. The semiconductor layer 203 may be formed of polycrystalline silicon, amorphous silicon or an oxide semiconductor. The gate insulating film 204 may be formed of silicon oxide or silicon nitride. The gate electrode 205 is formed of a metal material such as copper, molybdenum, tantalum, tungsten, aluminum or the like.

On the transistor 240, an interlayer insulating layer 206 covering the gate electrode 205 is provided. Contact holes are provided in the interlayer insulating layer 206. On the interlayer insulating layer 206, a source or drain electrode 207 and a drain or source electrode 208 are provided. The source or drain electrode 207 and the drain or source electrode 208 are connected with the semiconductor layer 203 via the contact holes in the interlayer insulating layer 206 and the gate insulating film 204. The interlayer insulating layer 206 may be formed of silicon oxide or silicon nitride. The source or drain electrode 207 and the drain or source electrode 208 are each formed of a metal material such as copper, titanium, molybdenum, aluminum or the like or an alloy thereof.

Although not shown in FIG. 5, the scanning lines 111 formed of the same metal material as that of the gate electrode 205 may be provided in the same layer as that of the gate electrode 205. The scanning lines 111 are connected with the scanning line driving circuit 104. The signal lines 112 extending in the direction crossing the scanning lines 111 may be provided in the same layer as that of source or drain electrode 207 and the drain or source electrode 208. The signal lines 112 are connected with the driver IC 106.

On the interlayer insulating layer 206, a flattening film 209 is provided. The flattening film 209 may be formed of an organic material such as, for example, polyimide, polyamide, acrylic resin, epoxy resin or the like. The flattening film 209 of such a material may be formed by a solution application method, and have a high effect of flattening. Although not specifically shown, the flattening film 209 is not limited to having a single-layer structure, and may have a stack structure of an organic insulating layer and an inorganic insulating layer.

On the flattening film 209, a protective film 211 is provided. The protective film 211 preferably has a barrier function against moisture and oxygen, and is preferably formed of, for example, a silicon nitride film or an aluminum oxide film.

A contact hole is provided in the flattening film 209 and the protective film 211. On the protective film 211, a pixel electrode 212 is provided. The pixel electrode 212 is connected with the source or drain electrode 207 via the contact hole. In the display device 100 according to this embodiment, the pixel electrode 212 acts as a positive electrode (anode) included in a light emitting element 250. The structure of the pixel electrode 212 varies in accordance with whether the display device 100 is of a top emission type or a bottom emission type. In the case where the display device 100 is of the top emission type, the pixel electrode 212 is formed of a metal material having a high reflectance or formed to have a stack structure of a transparent conductive layer having a high work function such as an indium oxide-based transparent conductive layer (i.e., ITO), a zinc oxide-based transparent conductive layer (i.e., IZO, ZnO) or the like and a metal film. In the case where the display device 100 is of the bottom emission type, the pixel electrode 212 is formed of any of the above-listed transparent conductive layers. In this embodiment, a case where the display device 100 is of the top emission type will be described.

On the pixel electrode 212, an insulating layer 213 is provided. The insulating layer 213 may be formed of polyimide, polyamide, acrylic resin, epoxy resin, siloxane or the like. The insulating layer 213 has an opening on a part of the pixel electrode 212. The part of the pixel electrode 212 exposed by the insulating layer 213 acts as a light emitting region LA of the light emitting element 250.

The insulating layer 213 is provided between the pixel electrodes 212 adjacent to each other so as to cover ends (edges) of the pixel electrodes 212, and acts as a member that isolates such adjacent pixel electrodes 212 from each other. Therefore, the insulating layer 213 is generally referred to also as a “partition” or a “bank”. It is preferred that the opening of the insulating layer 213 has a tapering inner wall. This may decrease a coverage fault at the time of formation of an organic layer described below.

On the pixel electrode 212, the organic layer is provided. The organic layer includes at least a light emitting layer 215 formed of an organic material, and acts as a light emitting portion of the light emitting element 250. The light emitting layer 215 emits light of a desired color. Namely, organic layers respectively including light emitting layers 215 emitting light of different colors are provided on the pixel electrodes 212 of the plurality of pixels 109, so that RGB colors may be displayed.

The organic layer includes a hole injection layer and/or hole transfer layer 214 and an electron injection layer and/or electron transfer layer 216 in addition to the light emitting layer 215. The hole injection layer and/or hole transfer layer 214 and the electron injection layer and/or electron transfer layer 216 extend across the plurality of pixels. The light emitting layer 215 is provided in each of the plurality of pixels 109.

On the electron injection layer and/or electron transfer layer 216 and the insulating layer 213, a counter electrode 217 is provided. The counter electrode 217 acts as a negative electrode (cathode) included in the light emitting element 250. The display device 100 according to this embodiment is of the top emission type, and therefore, the counter electrode 217 is formed of a transparent conductive layer. The transparent conductive layer may be formed of, for example, an MgAg thin film, ITO, IZO, ZnO or the like. The counter electrode 217 extends across the plurality of pixels. The counter electrode 217 is electrically connected with the terminals 107 via the conductive layers provided below the counter electrode 217 in the peripheral region around the display region 103. In FIG. 5, a region where the pixel electrode 212, the hole injection layer and/or hole transfer layer 214, the light emitting layer 215, the electron injection layer and/or electron transfer layer 216 and the counter electrode 217 overlap each other is referred to as the light emitting element 250. A layer, in the display region 103, in which the plurality of pixels 109 each including the light emitting element and the scanning line driving circuit 104 are provided is referred to as an “element formation layer 210”.

On the light emitting element 250, the sealing film 220 is provided. Provision of the sealing film 220 on the light emitting element 250 may suppress entrance of moisture or oxygen into the light emitting element 250, and thus may decrease deterioration of the light emitting element 250. This may improve the reliability of the display device 100.

On the sealing film 220, an insulating film 137 is provided. The insulating film 137 is formed of an inorganic insulating material. In the sealing film 220, at least a part of the connection electrode 116 is embedded. On the insulating film 137, the plurality of conductive layers 131 and the sensor electrode 115 are provided. The conductive layers 131 adjacent to each other in the left-right direction are connected with each other via the connection electrode 116. The connection electrode 116 includes a region crossing at least a part of the sensor electrode 115. The sensor electrode 114 and the sensor electrode 115 are included in the touch sensor.

A part of the sensor electrode 115 extends to the peripheral region 110 and is electrically connected with the wire 119 in the contact hole 118. Specifically, a part of the sensor electrode 115 is connected with the wire 119 via a conductive layer 221 provided in the contact hole 118 provided in the protective film 211 and the flattening film 209. The conductive layer 221 is formed in the same step as that of the pixel electrode 212, and therefore, is formed of the same material as that of the pixel electrode 212.

The wire 119 is exposed in the vicinity of an end of the peripheral region 110. Specifically, the wire 119 is connected with the flexible printed circuit board 108 via a conductive layer 223 and an anisotropic conductive film 224 provided in a contact hole 222 provided in the protective film 211 and the flattening film 209.

In the peripheral region 110, the bank 234 is provided on the protective film 211. The bank 234 is provided so as to surround at least the display region 103. Alternatively, the bank 234 may be provided so as to surround the display region 103 and the scanning line driving circuit 104. The bank 234 has a function of preventing an organic insulating layer 232 from spreading. Contact of an inorganic insulating layer 231 and an inorganic insulating layer 233 with each other on the bank 234 may suppress entrance of moisture or oxygen from the organic insulating layer 232. This may suppress entrance of moisture or oxygen into the light emitting element 250, and thus may decrease deterioration of the light emitting element 250. As a result, the reliability of the display device 100 may be improved.

A pressure-sensitive adhesive member 225 is provided so as to cover the display region 103 and a region where the sensor electrode 115 and the wire 119 are connected with each other. The pressure-sensitive adhesive member 225 may be formed of, for example, a pressure-sensitive adhesive material based on acrylic resin, rubber, silicone or urethane. The pressure-sensitive adhesive member 225 may contain a water-absorbing substance such as calcium, zeolite or the like. The water-absorbing substance contained in the pressure-sensitive adhesive member 225 may delay arrival of moisture to the light emitting element 250 even if the moisture enters the inside of the display device 100.

On the sensor electrode 114 and the sensor electrode 115, a circularly polarizing plate 228 is provided. Specifically, the circularly polarizing plate 228 is provided on the sensor electrode 114 and the sensor electrode 115, with the pressure-sensitive adhesive member 225 being provided between the circularly polarizing plate 228 and the sensor electrode 114/the sensor electrode 115. The circularly polarizing plate 228 has a stack structure including a ¼-wave plate 226 and a linearly polarizing plate 227. This structure allows light from the light emitting region LA to be released outside from a display-side surface of the substrate 102.

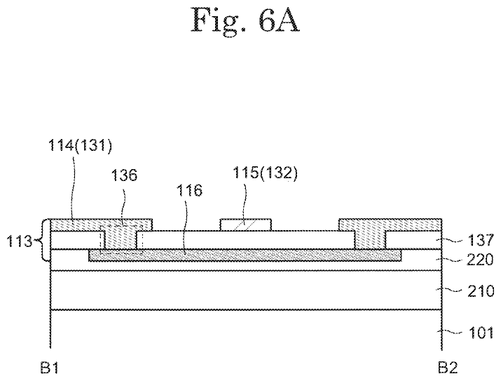

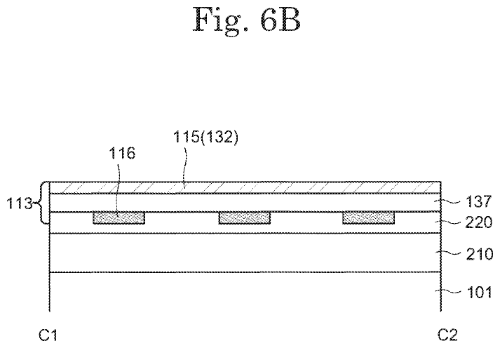

FIG. 6A shows a cross-sectional view taken along line B1-B2 in FIG. 4, and FIG. 6B shows a cross-sectional view taken along line C1-C2 in FIG. 4.

As shown in FIG. 6A and FIG. 6B, the element formation layer 210 is provided on the substrate 101. On the element formation layer 210, the sealing film 220 is provided.

As shown in FIG. 6A and FIG. 6B, the connection electrode 116 is embedded in the sealing film 220. Specifically, a side surface and a bottom surface of the connection electrode 116 are in contact with the sealing film 220. On the sealing film 220 and the connection electrode 116, the insulating layer 137 is provided. The insulating layer 137 electrically insulates the sensor electrode 114 and the sensor electrode 115 from each other, and also acts as a dielectric element to form a capacitance between the sensor electrode 114 and the sensor electrode 115. As shown in FIG. 6A, a contact hole 136 is provided in the insulating layer 137. On the insulating layer 137, the sensor electrode 114 and the sensor electrode 115 are provided. The conductive layer 131 of the sensor electrode 114 is connected with the connection electrode 116 via the contact hole 136 in the insulating layer 137. Namely, the connection electrode 116 may electrically connect the conductive layers 131 adjacent to each other in the left-right direction.

As shown in FIG. 6A, the sensor electrode 114 and the sensor electrode 115 may be provided on the insulating layer 137. Specifically, the conductive layer 131 and the conductive layer 132 may be formed on the same layer. This may substantially equalize the optical characteristics such as the reflectance or the like of both of the conductive layer 131 and the conductive layer 132. As a result, the sensor electrode 114 and the sensor electrode 115 may be made difficult to be visually recognized, namely, may be made inconspicuous.

In the case where the plurality of sensor electrodes 114 extending in the row direction and the plurality of sensor electrodes 115 extending in the column direction are provided on the same layer as described above, the sensor electrodes 114 and the sensor electrodes 115 need to be prevented from contacting each other in regions where the sensor electrodes 114 and the sensor electrodes 115 cross each other.

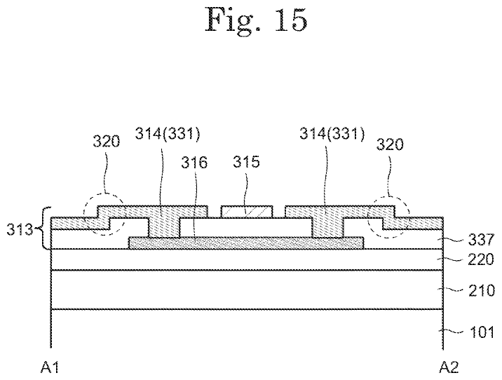

For example, as shown in FIG. 15, an insulating layer 337 is provided below a sensor electrode 314 and a sensor electrode 315 in order to prevent the sensor electrode 314 and the sensor electrode 315 from contacting each other. Below the insulating layer 337, a connection electrode 316 is provided to connect conductive layers 331, of the sensor electrode 314, adjacent to each other in the left-right direction. This may prevent the sensor electrode 314 and the sensor electrode 315 from contacting each other in a region where the sensor electrode 314 and the sensor electrode 315 cross each other.

However, in the case where the connection electrode 316 connecting the conductive layers 331 adjacent to each other in the left-right is provided on the sealing film 220, the insulating layer 337 provided on the connection electrode 136 has steps. In the case where the sensor electrode 314 is formed on the steps of the insulating layer 337, the possibility that the mesh wires of the sensor electrode 314 are disconnected in regions 320 is high. In the case where, for example, the sensor electrode 314 has a titanium/aluminum/titanium stack structure, the titanium films each have a small thickness of several ten nanometer and therefore are easily disconnected in the regions 320. In the regions where the wires are disconnected, a touch may not possibly be detected.

In such a situation, in the display device according to this embodiment, the connection electrode 116 connecting the conductive layers 131 adjacent to each other is embedded in the sealing film 220. In addition, a surface of the connection electrode 116 on the insulating layer 137 side is matched to a surface of the sealing film 220 on the insulating layer 137 side, or is located at a position lower than the surface of the sealing film 220 on the insulating layer 137 side. This may substantially flatten a surface of the layer in which the sensor electrode 114 and the sensor electrode 115 are provided. Therefore, the possibility that the mesh wires of the sensor electrode 114 is disconnected is decreased at an end of the connection electrode 116.

### [Layout of the Sensor Electrodes and the Pixels]

The sensor electrodes 114 and the sensor electrodes 115 according to this embodiment each include a lattice-shaped mesh wire. In other words, the sensor electrode 114 and the sensor electrodes 115 each have openings located in a matrix.

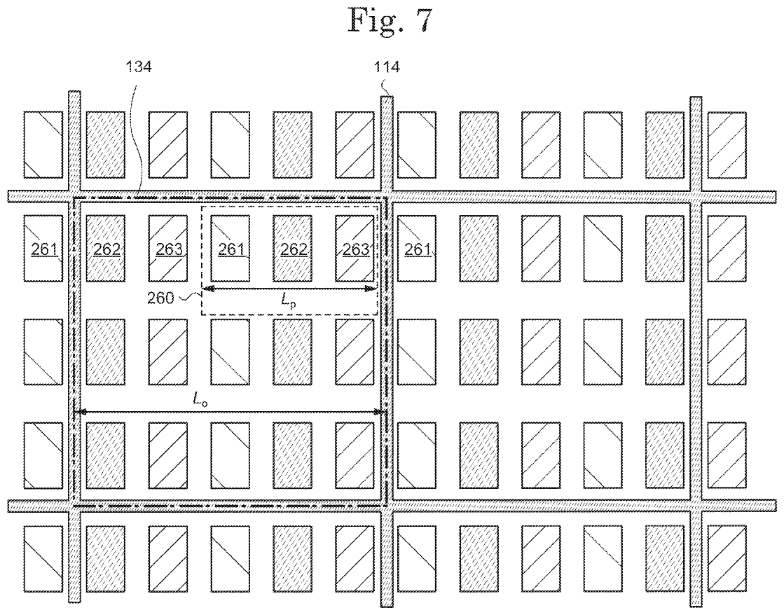

FIG. 7 shows sub pixels 261, 262 and 263 arrayed in stripes and the sensor electrode 114. As shown in FIG. 7, the openings of the sensor electrode 114 overlap light emitting regions of the sub pixels 261, 262 and 263. In other words, the light emitting regions of the sub pixels 261, 262 and 263 are located in regions overlapping the openings of the sensor electrode 114 and do not overlap the mesh wire of the sensor electrode 114.

Now, the sub pixels 261, 262 and 263 are respectively labelled as first sub pixels, second sub pixels and third sub pixels. It is assumed that colors provided by the first sub pixels, the second sub pixels and the third sub pixels are respectively a first color, a second color and a third color, and that the first color, the second color and the third color are different from each other. In the display region 103, one of the number of the sub pixels overlapping one opening, among the number of the first sub pixels overlapping one opening, the number of the second sub pixels overlapping one opening and the number of the third sub pixels overlapping one opening, may be different from each of the numbers of the other two sub pixels overlapping one opening. In, for example, the structure shown in FIG. 7, three sub pixels 261, six sub pixels 262 and six sub pixels 263 are located in one opening 134. The number of the sub pixels 261 is different from the number of the sub pixels 262 and the number of the sub pixels 263.

As shown in FIG. 7, the opening 134 may be provided such that length L0 of one side of the opening 134 is (n+k/m) times of length Lp of one side of the pixel 109. The vector of the length L0 and the vector of the length Lp are parallel to each other. n is an arbitrary natural number. m is the number of the sub pixels, included in one pixel 260, arrayed in a direction perpendicular to the vector of the length Lp. k is a natural number smaller than m. In the striped array shown in FIG. 7, m is 3, and L0 is (1+⅔) times of Lp. The vector of the length L0 and the vector of the length Lp may, for example, extend from the scanning line driving circuit 104 to be parallel with the scanning lines running across the display region 103.

A part of the sensor electrode 114 may be provided along the scanning line 111 extending from the scanning line driving circuit 104 and running across the display region 103, and include a region overlapping the scanning line 111. A part of the sensor electrode 115 may be provided along the signal line 112 extending from the driver IC 106 and running across the display region 103, and include a region overlapping the signal line 112.

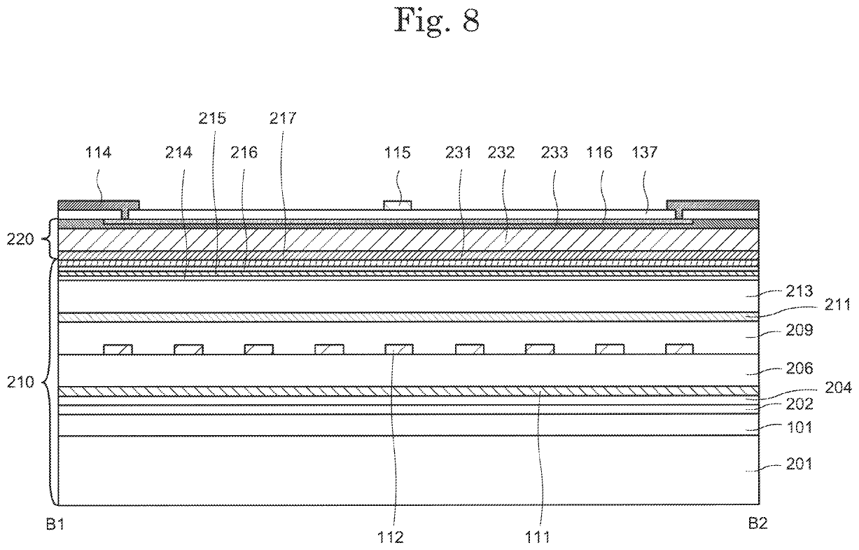

FIG. 8 shows a detailed cross-sectional view taken along line B1-B2 in FIG. 4. The connection electrode 116 is provided along the scanning line 111 and includes a region overlapping the scanning line 111. The sensor electrode 114, the sensor electrode 115 and the connection electrode 116 may be provided as overlapping the scanning line 111 in this manner, so as to be suppressed from overlapping the light emitting region of the light emitting element of the pixel 109. This may suppress a decrease in the aperture ratio of the pixel 109.

In the case where the layout of the sensor electrode 114 described above is adopted, the sub pixels providing different colors are located adjacent to the mesh wire at the same probability. Therefore, the dependence on the viewing angle with respect to the chromaticity is made equal among the sub pixels. As a result, the dependence on the viewing angle of the color of the entire image may be alleviated.

FIG. 7 shows the layout of the sensor electrode 114. The sensor electrode 115 may adopt substantially the same layout.

As described above, in the display device according to this embodiment, the connection electrode 116 connecting the conductive layers 131 adjacent to each other is formed so as to be embedded in the sealing film 220. A surface of the connection electrode 116 on the insulating layer 137 side is matched to a surface of the sealing film 220 on the insulating layer 137 side, or is located at a position lower than the surface of the sealing film 220 on the insulating layer 137 side. This may substantially flatten a surface of the layer in which the sensor electrode 114 and the sensor electrode 115 are provided. Therefore, the possibility that the mesh wires of the sensor electrode 114 is disconnected is decreased at an end of the connection electrode 116.

### [Method for Producing the Sealing Film and the Touch Sensor]

Now, a method for producing the sealing film and the touch sensor included in the display device according to this embodiment will be described, with reference to FIG. 9A to FIG. 9F. FIG. 9A to FIG. 9F are each a cross-sectional view taken along line B1-B2 in FIG. 4.

First, as shown in FIG. 9A, the sealing film 220 is formed on the element formation layer 210. Specifically, the sealing film 220 is formed on the negative electrode of the light emitting element. In this embodiment, in order to form the sealing film 220, the inorganic insulating layer 231, the organic insulating layer 232 and the inorganic insulating layer 233 are sequentially formed. It is preferred that the inorganic insulating layer 231 and the inorganic insulating layer 233 are fine films in order to prevent permeation of moisture. In the case where the sealing film is formed only of an inorganic insulating layer, the sealing film may possibly be broken when the display device is bent. Therefore, it is preferred that an organic insulating layer, which is more flexible than the inorganic insulating layer, is used and the inorganic insulating layers and the organic insulating layer are stacked alternately, so as to form the sealing film 220.

The inorganic insulating layer 231 and the inorganic insulating layer 233 may each be formed of a film of, for example, silicon nitride (SiₓN_{y}), silicon oxide nitride (SiOₓN_{y}), silicon nitride oxide (SiNₓO_{y}), aluminum oxide (AlₓO_{y}), aluminum nitride (AlₓN_{y}), aluminum oxide nitride (AlₓO_{y}N_{z}), aluminum nitride oxide (AlₓN_{y}O_{z}) or the like (x, y and z are arbitrary numerals). It is preferred that the inorganic insulating layer 231 has a thickness of 500 nm or greater and 1000 nm or less. It is preferred that the inorganic insulating layer 233 has a thickness of 500 nm or greater and 1000 nm or less. The organic insulating layer 232 may be formed of polyimide resin, acrylic resin, epoxy resin, silicone resin, fluorine resin, siloxane resin or the like. It is preferred that the organic insulating layer 232 has a thickness of 5 μm or greater and 15 μm or less. The above-mentioned ranges of the thicknesses of the inorganic insulating layer 231, the organic insulating layer 232 and the inorganic insulating layer 233 are preferred because in the case where the thicknesses of the layers are in the above-mentioned ranges, moisture and oxygen may be suppressed from permeating these layers and thus may be suppressed from reaching the light emitting element, while the flexibility of the display device is guaranteed.

Next, the touch sensor is formed on the sealing film 220. First, as shown in FIG. 9B, a recessed portion 138 is formed in the inorganic insulating layer 233. The recessed portion 138 may be formed as follows: a mask is formed on the inorganic insulating layer 233 and then, the inorganic insulating layer 233 is etched. It is preferred that the recessed portion 138 has a depth matched to a thickness of the connection electrode 116 to be formed in a later step. For example, it is preferred that the recessed portion 138 has a depth of 50 nm or greater and 200 nm or less.

Next, as shown in FIG. 9C, a conductive layer 116a is formed to fill the recessed portion 138 formed in the inorganic insulating layer 233. The conductive layer 116a may be formed by, for example, printing or applying a conductive paste such as a silver paste or the like. Alternatively, the conductive layer 116a may be formed by, for example, printing or applying a composition containing a metal nanowire. The metal nanowire may be of gold, silver, platinum, copper or the like. A silver nanowire, which is highly conductive and highly visually recognizable, is preferred.

Next, as shown in FIG. 9D, after the conductive layer 116a is formed to fill the recessed portion 138 in the inorganic insulating layer 233, a surface of the conductive layer 116a and the inorganic insulating layer 233 is subjected to a flattening process. A preferred flattening process is, for example, a chemical mechanical polishing (CMP) process or an etch-back process. The “etch-back process” is retracting a surface of a film in a thickness direction by highly anisotropic etching (e.g., dry etching). The flattening process performed on the surface of the conductive layer 116a and the inorganic insulating layer 233 may result in formation of the connection electrode 116. At least a part of the connection electrode 116 is embedded in the inorganic insulating layer 233. Specifically, a side surface and a bottom surface of the connection electrode 116 are in contact with the inorganic insulating layer 233. The inorganic insulating layer 233 is provided between the connection electrode 166 and the organic insulting layer 232. In this step, it is preferred that a top surface of the connection electrode 116 generally matches a top surface of the sealing film. Herein, the expression “generally matches” encompasses a case where the top surface of the connection electrode 116 is within the range of about ±10 nm with respect to the surface of the inorganic insulating layer 233. The thickness of the connection electrode 116 is determined in accordance with the depth of the recessed portion 138 provided in the inorganic insulating layer 233.

Next, as shown in FIG. 9E, the insulating layer 137 is formed on the connection electrode 116 and the inorganic insulating layer 233. The insulating layer 137 may be formed of an inorganic insulating layer such as, for example, a silicon oxide film, a silicon nitride film or the like. It is preferred that the insulating layer 137 has a thickness of 100 nm or greater and 300 nm or less. Next, the contact hole 136 is formed in the insulating layer 137 to expose a part of the connection electrode 116.

Next, on the insulating layer 137, a conductive film is formed. The conductive film may be formed of, for example, aluminum (Al), titanium (Ti), chromium (Cr), cobalt (Co), nickel (Ni), zinc (Zn), molybdenum (Mo), copper (Cu), indium (In), tin (Sn), hafnium (Hf), tantalum (Ta), tungsten (W), platinum (Pt), bismuth (Bi) or the like. Alternatively, an alloy of these metal materials may be used. Still alternatively, a conductive oxide such as ITO (indium tin oxide), IGO (indium gallium oxide), IZO (indium zinc oxide), GZO (zinc oxide containing gallium as a dopant) or the like may be used. The conductive film may have a single-layer structure or a stack structure.

Next, the conductive film is masked and etched to form the plurality of conductive layers 131 and the plurality of conductive layers 132. As a result of the etching, the plurality of conductive layers 131 each have the plurality of openings 134 arrayed in a matrix. Similarly, the plurality of conductive layers 132 each have the plurality of openings 135 arrayed in a matrix. As a result, the conductive layers 131 and the conductive layers 132 may each have a mesh form. The conductive layers 131 adjacent to each other may be connected with each other by the connection region 116 so as to act as the sensor electrode 114. The conductive layers 132 adjacent to each other may be connected with each other via the connection electrode 139 embedded in the inorganic insulating layer 233 so as to act as the sensor electrode 115.

The sealing film and the touch sensor 113 may be formed by the above-described steps (see FIG. 9F).

In the display device according to this embodiment, the connection electrode 116 connecting the conductive layers 131 adjacent to each other is formed so as to be embedded in the sealing film 220. In addition, a surface of the connection electrode 116 on the insulating layer 137 side is generally is matched to a surface of the sealing film 220 on the insulating layer 137 side, or is located at a position lower than the surface of the sealing film 220 on the insulating layer 137 side. This may substantially flatten a surface of the layer in which the sensor electrode 114 and the sensor electrode 115 are provided. Therefore, the possibility that the mesh wires of the sensor electrode 114 is disconnected is decreased at an end of the connection electrode 116.

### Embodiment 2

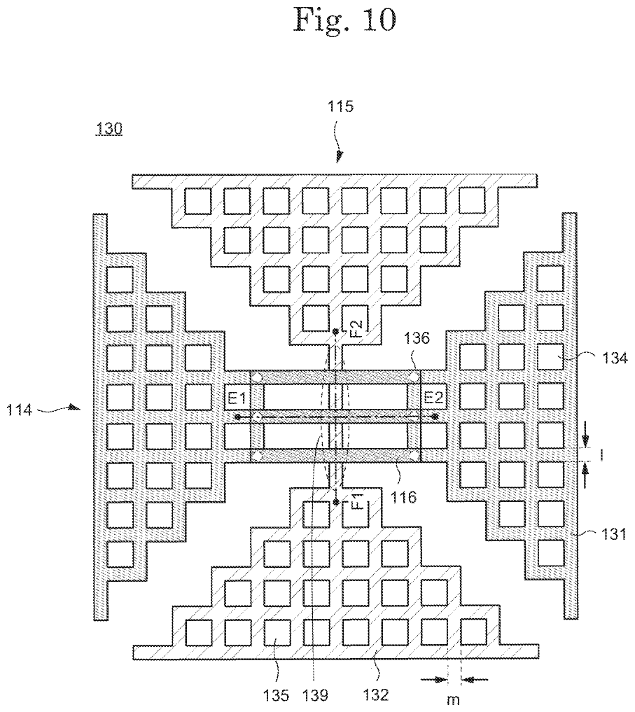

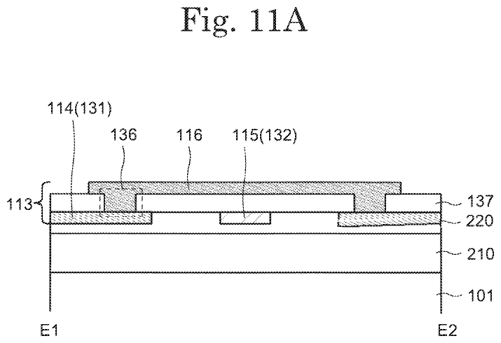

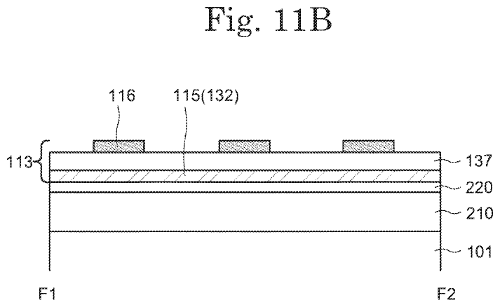

In this embodiment, a structure in which the sensor electrode 114 and the sensor electrode 115 are embedded in the sealing film 220 and the connection electrode 116 is provided on the insulating layer 137 will be described with reference to FIG. 10, FIG. 11A and FIG. 11B.

FIG. 10 shows an enlarged view of a region of a part of the touch sensor. Similarly to the touch sensor shown in FIG. 4, the conductive layers 131, of the sensor electrode 114, adjacent to each other in the left-right direction are connected with each other via the connection electrode 116. The conductive layers 132, of the sensor electrode 115, adjacent to each other in the up-down direction are connected with each other via the connection region 139. The plurality of conductive layers 131 included in the sensor electrode 114 each have the plurality of openings 134, and the plurality of conductive layers 132 included in the sensor electrode 115 each have the plurality of openings 135. Respectively in each conductive layer 131 and each conductive layer 132, the plurality of openings 134 and the plurality of openings 135 are arrayed in a matrix. As a result, the conductive layers 131 and the conductive layers 132 each have a mesh form (or a lattice form). Width I of the wire forming each conductive layer 131 is 1 μm or greater and 10 μm or less, or 2 μm or greater and 8 μm or less, and typically 5 μm. Similarly, width m of the wire forming each conductive layer 132 is 1 μm or greater and 10 μm or less, or 2 μm or greater and 8 μm or less, and typically 5 μm.

Although not shown in FIG. 10, the sealing film 220 may include the inorganic insulating layer 231, the organic insulating layer 232 and the inorganic insulating layer 233 like in FIG. 9A in embodiment 1. In the case where the inorganic insulating layer 231, the organic insulating layer 232 and the inorganic insulating layer 233 are stacked sequentially from the side of the light emitting element 250, the conductive layers 131 and the conductive layers 132 are embedded in the inorganic insulating layer 233 at least partially. Namely, a side surface and a bottom surface of each conductive layer 131 and a side surface and a bottom surface of each conductive layer 132 are in contact with the inorganic insulating layer 233.

As shown in FIG. 10, the connection electrode 116 connecting the conductive layers 131 adjacent to each other in the left-right direction is provided to extend in the first direction, and the connection region 139 connecting the conductive layers 132 adjacent to each other in the up-down direction is provided to extend in the second direction crossing the first direction. In other words, the connection electrode 116 includes a region crossing a part of the sensor electrode 115.

FIG. 11A shows a cross-sectional view taken along line E1-E2 in FIG. 10, and FIG. 11B shows a cross-sectional view taken along line F1-F2 in FIG. 10.

As shown in FIG. 11A and FIG. 11B, the element formation layer 210 is provided on the substrate 101, and the sealing film 220 is provided on the element formation layer 210.

As shown in FIG. 11A and FIG. 11B, the sensor electrode 114 and the sensor electrode 115 are embedded in the sealing film 220. The insulating layer 137 also acts as a dielectric member that electrically insulates the sensor electrode 114 and the sensor electrode 115 from each other. As shown in FIG. 11A, the contact hole 136 is provided in the insulating layer 137. On the insulating layer 137, the connection electrode 116 is provided. The conductive layer 131 of the sensor electrode 114 is connected with the connection electrode 116 via the contact hole 136 in the insulating layer 137. Namely, the connection electrode 116 may electrically connect the conductive layers 131 adjacent to each other in the left-right direction.

As shown in FIG. 11A, the sensor electrode 114 and the sensor electrode 115 may be embedded in the sealing film 220. This may substantially equalize the optical characteristics such as the reflectance or the like of both of the sensor electrode 114 and the sensor electrode 115. As a result, the sensor electrode 114 and the sensor electrode 115 may be made difficult to be visually recognized, namely, may be made inconspicuous.

In the display device according to this embodiment, the sensor electrode 114 and the sensor electrode 115 are embedded in the sealing film 220. In addition, a surface of the sensor electrode 114 on the insulating layer 137 side and a surface of the sensor electrode 115 on the insulating layer 137 side are matched to a surface of the sealing film 220 on the insulating layer 137 side, or are located at a position lower than the surface of the sealing film 220 on the insulating layer 137 side. This may decrease the possibility that the mesh wires of the sensor electrode 114 and the sensor electrode 115 are disconnected.

### Embodiment 3

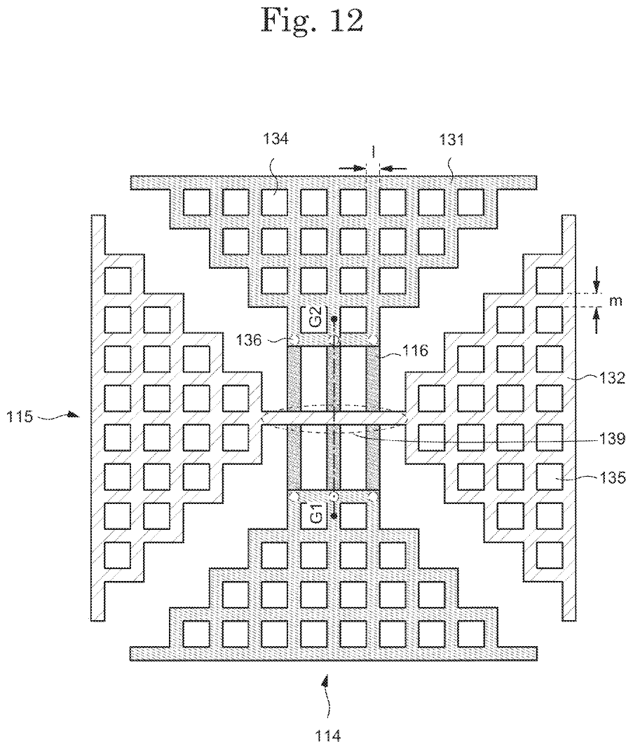

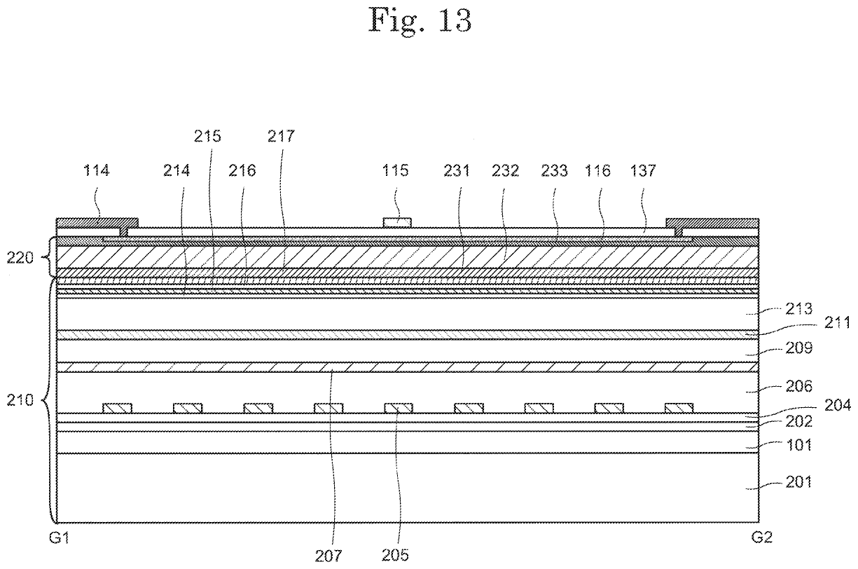

In this embodiment, a layout partially different from the layout of the sensor electrodes 114 and the sensor electrodes 115 of the touch sensor in embodiment 1 will be described with reference to FIG. 12 and FIG. 13.

FIG. 12 shows an enlarged view of a part of the touch sensor. The conductive layers 131, of the sensor electrodes 114, adjacent to each other in the up-down direction are connected with each other via the connection electrode 116. The conductive layers 132, of the sensor electrodes 115, adjacent to each other in the left-right direction are connected with each other via the connection region 139. The plurality of conductive layers 131 included in the sensor electrode 114 each have the plurality of openings 134, and the plurality of conductive layers 132 included in the sensor electrode 115 each have the plurality of openings 135. Respectively in each conductive layer 131 and each conductive layer 132, the plurality of openings 134 and the plurality of openings 135 are arrayed in a matrix. As a result, the conductive layers 131 and the conductive layers 132 may each have a mesh form.

As shown in FIG. 12, the connection electrode 116 connecting the conductive layers 131 adjacent to each other in the up-down direction is provided to extend in the second direction, and the connection region 139 connecting the conductive layers 132 adjacent to each other in the left-right direction is provided to extend in the first direction. In other words, the connection electrode 116 includes a region crossing a part of the sensor electrode 115. In FIG. 12, the connection electrode 116 is shown as having a width that is the same as the width I of the conductive layer 131. Alternatively, the width of the connection electrode 116 may be greater than the width I of the conductive layer 131. It is preferred that the connection electrode 116 does not overlap the light emitting region of the light emitting element of the pixel.

A part of the sensor electrode 114 may be provided along the scanning line 111 extending from the scanning line driving circuit 104 and running across the display region 103, and include a region overlapping the scanning line 111. A part of the sensor electrode 115 may be provided along the signal line 112 extending from the driver IC 106 and running across the display region 103, and include a region overlapping the signal line 112.

FIG. 13 shows a detailed cross-sectional view taken along line G1-G2 in FIG. 12. The connection electrode 116 is provided along the scanning line 111 and includes a region overlapping the scanning line 111. The sensor electrode 114, the sensor electrode 115 and the connection electrode 116 may be provided as overlapping the signal line 112 in this manner, so as to be suppressed from overlapping the light emitting region of the light emitting element of the pixel 109. This may suppress a decrease in the aperture ratio of the pixel 109.

### Embodiment 4

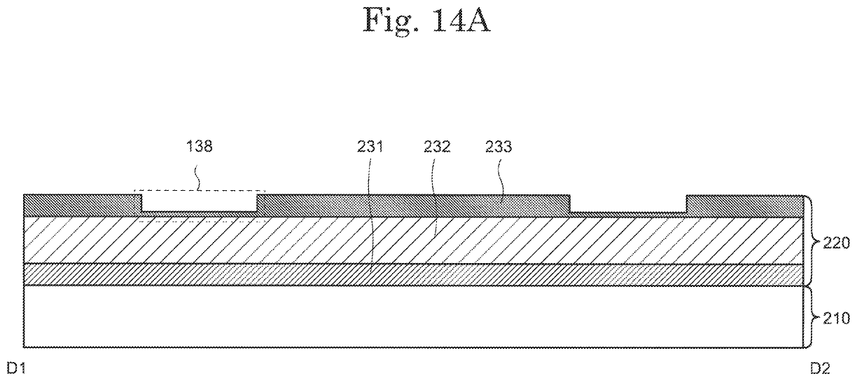

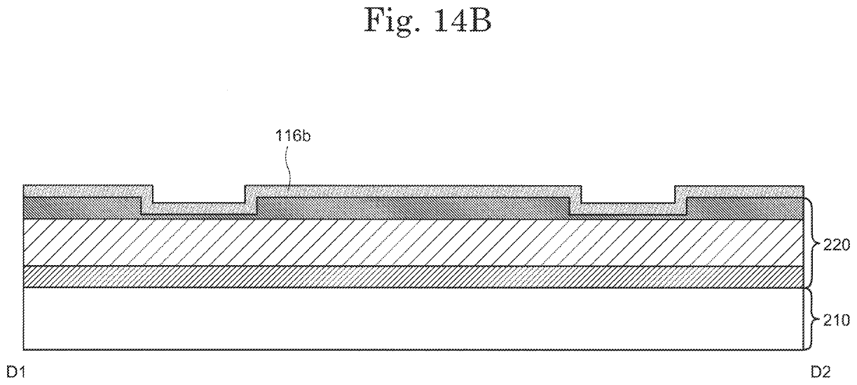

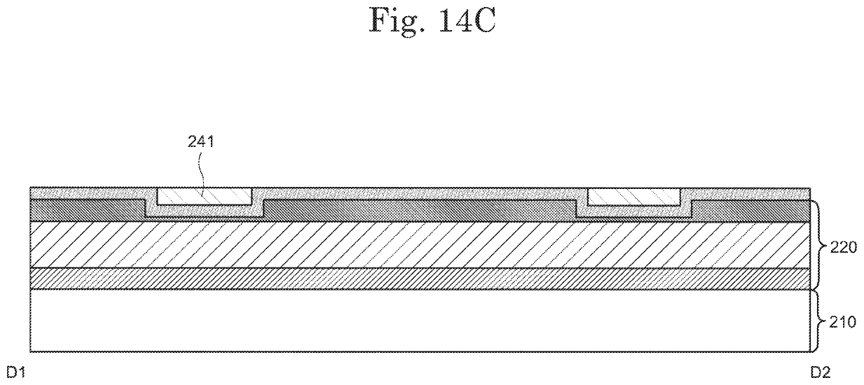

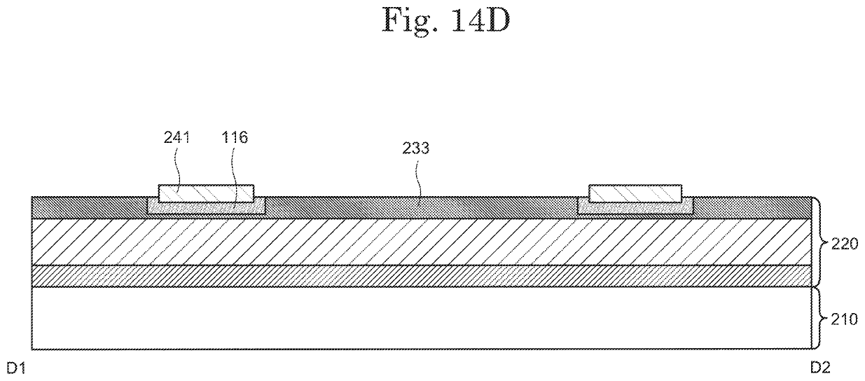

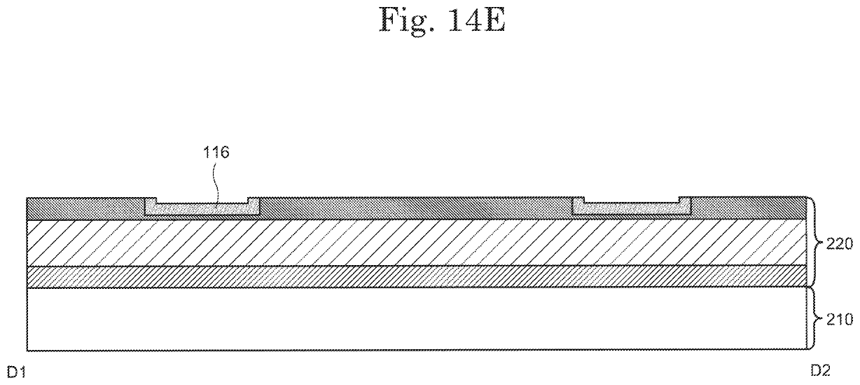

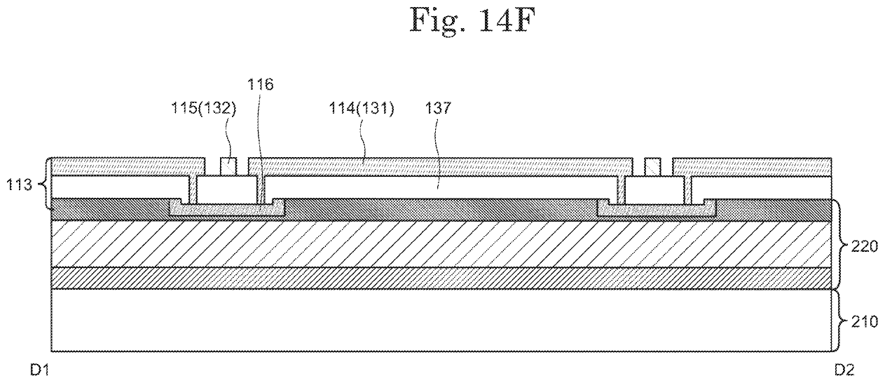

In this embodiment, a production method partially different from the method for producing the sealing film and the touch sensor shown in FIG. 9A to FIG. 9F will be described with reference to FIG. 14A to FIG. 14F. FIG. 14A to FIG. 14F are each a cross-sectional view taken along line B1-B2 in FIG. 4. Descriptions on steps substantially the same as those shown in FIG. 9A to FIG. 9F may be omitted.

First, the sealing film 220 is formed on the element formation layer 210. The sealing film 220 is formed to have a stack structure including the inorganic insulating layer 231, the organic insulating layer 232 and the inorganic insulating layer 233. Regarding the detailed description of the sealing film 220, the description regarding FIG. 9A may be referred to.

Next, as shown in FIG. 14A, the recessed portion 138 is formed in the inorganic insulating layer 233 of the sealing film 220. The recessed portion 138 may be formed as follows: a mask is formed on the inorganic insulating layer 233 and then, the inorganic insulating layer 233 is etched. It is preferred that the recessed portion 138 has a depth of, for example, 50 nm or greater and 200 nm or less.

Next, as shown in FIG. 14B, a conductive layer 116b is formed on the sealing film 220. The conductive layer 116b may be formed of, for example, aluminum (Al), titanium (Ti), chromium (Cr), cobalt (Co), nickel (Ni), zinc (Zn), molybdenum (Mo), copper (Cu), indium (In), tin (Sn), hafnium (Hf), tantalum (Ta), tungsten (W), platinum (Pt), bismuth (Bi) or the like. Alternatively, an alloy of these metal materials may be used. Still alternatively, a conductive oxide such as ITO (indium tin oxide), IGO (indium gallium oxide), IZO (indium zinc oxide), GZO (zinc oxide containing gallium as a dopant) or the like may be used. The conductive film 116b may have a single-layer structure or a stack structure. The conductive film 116b has, for example, a titanium/aluminum/titanium stack structure. It is preferred that the conductive film 116b has a thickness of 50 nm or greater and 200 nm or less.

Next, as shown in FIG. 14C, a resist 241 is formed in a recessed portion formed by the recessed portion 138 and the conductive film 116b. Next, as shown in FIG. 14D, the conductive film 116b is subjected to an etch-back process to expose a surface of the inorganic insulating layer 233. The “etch-back process” is a process of removing the conductive film 116b in a thickness direction by anisotropic etching. Then, as shown in FIG. 14E, the resist 241 is removed, so that the connection electrode 116 may be formed. The connection electrode 116 is provided such that a side surface and a bottom surface thereof are in contact with the inorganic insulating layer 233. The inorganic insulating layer 233 is provided between the connection electrode 116 and the organic insulating layer 232. In this step, it is preferred that a surface of the connection electrode 116 is lower than a surface of the sealing film. Specifically, it is preferred that surface of the connection electrode 116 is lower by 10 nm or greater than the surface of the inorganic insulating layer 233.

Next, like in FIG. 9E, the insulating layer 137 is formed on the connection electrode 116 and the inorganic insulating layer 233. The insulating layer 137 may be formed of an inorganic insulating layer of, for example, silicon oxide, silicon nitride or the like. It is preferred that the insulating layer 137 has a thickness of 100 nm or greater and 300 nm or less. Next, the contact hole 136 is formed in the insulating layer 137 to expose a part of the connection electrode 116.

Next, like in FIG. 9F, a conductive film is formed on the insulating layer 137. Next, the conductive film is masked and etched to form the plurality of conductive layers 131 and the plurality of conductive layers 132. As a result of the etching, the plurality of conductive layers 131 each have the plurality of openings 134 arrayed in a matrix. Similarly, the plurality of conductive layers 132 each have the plurality of openings 135 arrayed in a matrix. As a result, the conductive layers 131 and the conductive layers 132 may each have a mesh form. The conductive layers 132 adjacent to each other may be connected with each other by the connection region 139 so as to act as the sensor electrode 115. The conductive layers 131 adjacent to each other may be connected with each other via the connection electrode 116 embedded in the inorganic insulating layer 233 so as to act as the sensor electrode 114.

The sealing film 220 and the touch sensor 113 may be formed by the above-described steps (see FIG. 14F).

In the display device according to this embodiment, the connection electrode 116 connecting the conductive layers 131 adjacent to each other is formed so as to be embedded in the sealing film 220. In addition, a surface of the connection electrode 116 on the insulating layer 137 side is located at a position lower than a surface of the sealing film 220 on the insulating layer 137 side. This may substantially flatten a surface of the layer in which the sensor electrode 114 and the sensor electrode 115 are provided. Therefore, the possibility that the mesh wires of the sensor electrode 114 is disconnected is decreased at an end of the connection electrode 116.

In the method for producing the sealing film 220 and the touch sensor 113 shown in FIG. 14A to FIG. 14F, the connection electrode 116 is embedded in the inorganic insulating layer 233. The present invention is not limited to this. The sensor electrode 114 and the sensor electrode 115 may be embedded in the inorganic insulating layer 233.

Specifically, as described above in embodiment 2, the conductive layer 131 included in the sensor electrode 114 and the sensor electrode 115 are formed so as to be embedded in the sealing film 220. Namely, the conductive layer 131 included in the sensor electrode 114 and the sensor electrode 115 are provided such that a side surface and a bottom surface thereof are in contact with the inorganic insulating layer 233. The inorganic insulating layer 233 is provided between the conductive layer 131 included in the sensor electrode 114/the sensor electrode 115 and the organic insulating layer 232. The conductive layer 131 included in the sensor electrode 114 and the sensor electrode 115 are formed to be lower than a surface of the sealing film 220 on the insulating layer 137 side. This may substantially flatten a surface of the layer in which the sensor electrode 114 and the sensor electrode 115 are provided. Therefore, the possibility that the connection electrode 116 of sensor electrode 114 is disconnected is decreased at an end of the connection electrode 115.

Embodiments according to the present invention are described above. The present invention is not limited to the embodiment described above, and may be modified in any of various manners without departing from the gist of the present invention. Needless to say, such modifications are encompassed in the scope of the present invention.

What is claimed is:

1. A display device comprising:
a display region including a plurality of pixels each including a light emitting element;
a sealing film provided on the display region;
an insulating layer provided on the sealing film;
a first sensor electrode including a first conductive layer and a second conductive layer provided on the insulating layer and a connection electrode covered with the insulating layer, at least a part of the connection electrode being embedded in the sealing film; and
a second sensor electrode provided on the insulating layer,
wherein
the first conductive layer is connected to the second conductive layer via the connection electrode, and
the connection electrode includes a region crossing at least a part of the second sensor electrode.

2. The display device according to claim 1, wherein the insulating layer is formed of an inorganic insulating material.

3. The display device according to claim 1, further comprising a bank surrounding the plurality of pixels in the display region,
wherein one of the first conductive layer and the second conductive layer includes a region overlapping the bank.

4. The display device according to claim 1, further comprising a circularly polarizing plate on the first sensor electrode and the second sensor electrode.

5. The display device according to claim 1, further comprising:
a scanning line extending in a first direction, and
a signal line extending in a second direction crossing the first direction,
wherein the connection electrode includes a region overlapping the scanning line.

6. The display device according to claim 1, wherein:
the first sensor electrode and the second sensor electrode each include a plurality of openings, and
the plurality of openings overlap a light emitting region of the light emitting element included in at least one of the pixels.

7. The display device according to claim 1, wherein:
the sealing film includes a first inorganic insulating layer, an organic insulating layer and a second inorganic insulating layer stacked from the side of the display region, and
at least a part of the connection electrode is embedded in the second inorganic insulating layer.

8. The display device according to claim 7, wherein the second inorganic insulating layer is provided between the connection electrode and the organic insulating layer.

9. The display device according to claim 1, wherein a surface of the connection electrode at an insulating layer side matches a surface of the sealing film at an insulating layer side.

10. The display device according to claim 1, wherein a surface of the connection electrode at an insulating layer side is at a position lower than a surface of the sealing film at an insulating layer side.

11. A display device comprising:
a display region including a plurality of pixels each including a light emitting element;
a sealing film provided on the display region;
an insulating layer provided on the sealing film;
a first sensor electrode including a connection electrode provided on the insulating layer and a first conductive layer and a second conductive layer covered with the insulating layer, at least a part of the first conductive layer e being embedded in the sealing film, at least a part of the second conductive layer e being embedded in the sealing film; and
a second sensor electrode, at least a part of the second electrode being embedded in the sealing film,
wherein
the first conductive layer is connected to the second conductive layer via the connection electrode, and
the connection electrode includes a region crossing at least a part of the second sensor electrode.

12. The display device according to claim 11, further comprising a bank surrounding the plurality of pixels in the display region,
wherein one of the first conductive layer and the second conductive layer includes a region overlapping the bank.

13. The display device according to claim 11, wherein:
the first sensor electrode and the second sensor electrode each include a plurality of openings, and
the plurality of openings overlap a light emitting region of the light emitting element included in at least one of the pixels.

14. The display device according to claim 11, wherein:
the sealing film includes a first inorganic insulating layer, an organic insulating layer and a second inorganic insulating layer stacked in this order from the display region, and
at least a part of the first sensor electrode and at least a part of the second sensor electrode are embedded in the second inorganic insulating layer.

15. The display device according to claim 14, wherein the second inorganic insulating layer is provided between the first conductive layer/the second conductive layer/the second sensor electrode and the organic insulating layer.

16. A display device comprising:
a display region including a plurality of pixels each including a light emitting element;
an organic insulating layer provided above the plurality of pixels and covering the plurality of pixels;
a first inorganic insulating layer in contact with the organic insulating layer, the organic insulating layer being located between the first inorganic insulating layer and the plurality of pixels;
a second inorganic insulating layer in contact with the first inorganic insulating layer, the first inorganic insulating layer being located between the second inorganic insulating layer and the organic insulating layer;
a first sensor electrode including a first conductive layer and a second conductive layer in contact with the second inorganic insulating layer, the first conductive layer and the second conductive layer being separate from each other and located at a same layer;
a connection electrode connecting the first conductive layer to the second conductive layer, the second inorganic insulating layer being located between the first sensor electrode and the connection electrode; and
a second sensor electrode located at a same layer as that of the first sensor electrode,
wherein
the first inorganic insulating layer includes a first recessed portion,
one of the first sensor electrode and the connection electrode is located between the first inorganic insulating layer and the second inorganic insulating layer,
at least a part of the one of the first sensor electrode and the connection electrode is located in the first recessed portion, and
the connection electrode includes a region crossing at least a part of the second sensor electrode.

17. The display device according to claim 16, further comprising a third inorganic insulating layer covering the plurality of pixels,
wherein the third inorganic insulating layer is provided between the plurality of pixels and the organic insulating layer.

18. The display device according to claim 16, further comprising a bank surrounding the plurality of pixels in the display region,
wherein one of the first conductive layer and the second conductive layer includes a region overlapping the bank.

19. The display device according to claim 16, wherein:
the first sensor electrode and the second sensor electrode each include a plurality of openings, and
the plurality of openings overlap a light emitting region of the light emitting element included in at least one of the pixels.

20. The display device according to claim 16, wherein the connection electrode includes a second recessed portion located in the first recessed portion, overlapping the first recessed portion as seen in a plan view, and being smaller than the first recessed portion.
